(19) United States
(12) Patent Application Publication
(10) Pub. No.: US 2005/0014299 A1
(43) Pub. Date: Jan. 20, 2005

(54) Control of metal resistance in semiconductor products via integrated metrology

(75) Inventors: Susie Xiuru Yang, Sunnyvale, CA (US); Lawrence Chung-Lai Lei, Milpitas, CA (US)

Correspondence Address: Applied Materials, Inc., P.O. Box 450A, Santa Clara, CA, 95052, US

(73) Assignee: Applied Materials, Inc., Santa Clara, CA (US)

(21) Appl. No.: 10/809,908

(22) Filed: Mar. 26, 2004

Related U.S. Application Data
(60) Provisional application No. 60/486,924, filed on Jul. 15, 2003.

(51) Int. Cl. H01L 21/66

(52) U.S. Cl. 438/16

(57) ABSTRACT

Systems, methods and computer-readable mediums are provided for improving and controlling uniformity of resistance (RS) of metal line, e.g., copper, conductivity in semiconductor processing. In-line or integrated metrology and data feedback and/or feed-forward may be used for monitoring and adjusting the chemical mechanical planarization (CMP) process. Measurements are obtained of deposition layer thickness after the chemical vapor deposition (CVD) process, and of the copper trench profile, including depth, top critical dimension, and bottom critical dimension, following the Etch process. The trench profile measurements are used as feed forward information, together with the CVD measurement, in adjusting the removal rate at the CMP to leave an acceptable amount of material in the copper cross section in the semiconductor product, so that a target resistance is attained.

### RELATED APPLICATIONS

This application claims priority to U.S. Provisional Application Ser. No. 60/486,924, filed Jul. 15, 2003, and expressly incorporated herein by reference.

### BACKGROUND OF THE INVENTION

1. Field of the Invention

The present invention concerns computer-related and/or assisted methods, systems and computer readable mediums for use in connection with semiconductor manufacturing. More specifically, it relates to quantifying and improving control of resistance of metal lines, for example during the process of manufacturing semiconductor chips.

2. Related Art

In a manufacturing system, products are manufactured on processing equipment such as a series of manufacturing tools. One goal in connection with manufacturing systems for semiconductor wafers is to improve the performance of the products (chips). An important part of product performance is the metal lines formed on the chips, and in particular the resistance of the metal.

Metal lines, typically copper (in a damascene process), are formed in semiconductor chips, by placing a dielectric layer on a wafer, and etching a pattern in the layer using standard procedures. Barrier films and copper (or other metal) are then deposited on the patterned surface. Next, a portion of the copper surface topography and the top film is removed by chemical mechanical planarization (CMP).

In the course of implementing the aforementioned process, metal loss may occur, including for example oxide loss, dishing and/or erosion. Dishing may occur in the metal lines, where the polished metal is typically lower than the polished surrounding barrier film. Dishing may be defined as a difference in height between a lowest point of a single metal line/bond pad (usually at the center of the structure) and the surrounding film, usually oxide. Erosion is a similar effect on an array of fine metal/dielectric lines. These types of metal recess introduce problems into chip performance, as they reduce dielectric spacing and the amount of metal in chip interconnects.

The amount of copper (or other metal) in, for example, the metal lines of a semiconductor chip ultimately affects the resistance (Rs), that is, it affects the conductance of electrical signals in the final semiconductor chip. Since increased copper (or other metal) line resistance results in lower conductivity of electrical signals and hence results in deterioration of chip performance, a need has arisen for the continuing improvement of monitoring and control over wiring RS variance in semiconductor processing by controlling the amount of metal that exist within aspects of the final semiconductor chip.

As can be appreciated from the above, resistance of the metal line is principally determined by two processes: etch, which produces a trench of a specified geometry; and chemical mechanical planarization (CMP), which can remove excess electro-chemical-plating (ECP) metal, e.g., copper. These two processes control to a significant degree the amount of metal in the final semiconductor product, and hence control the conductivity and resistance.

Unfortunately, conventional techniques fail to consider the amount of metal remaining in the semiconductor product after implementation of the aforementioned processes. For example, they do not take into consideration the area of one or more cross sections of the copper (or other metal) to determine whether the amount of metal therein adversely affects an expected/targeted amount of resistance.

Consequently, there remains a need for a process to significantly reduce the variance of the wiring resistance, wherein the process avoids or minimizes creating the need for new and/or time-consuming measurements.

### SUMMARY OF THE INVENTION

The present invention alleviates the problems of the conventional techniques described above by providing systems, methods and mediums for determining the area of the copper (and/or other metal) within a portion or entirety of a semiconductor device, and using the determination to effectively and reliably monitor and control resistance variation. The various measurements that might be used to calculate the area of copper might be individually collected at different points of the semiconductor manufacturing process and utilized in a coordinated fashion to use in calculating the amount of metal and hence the wiring resistance. The amount of metal is quantified, the wiring resistance is determined and the variation in resistance may be monitored and controlled, both wafer-to-wafer (WTW) and within-wafer (WIW), utilizing feedback and feed forward, techniques.

One or more embodiments of the present invention provide for improved control and uniformity of resistance (Rs) of copper conductivity by using in-line and/or integrated metrology for monitoring and adjusting the dielectric deposition, lithography, dielectric etch, and chemical mechanical planarization (CMP) process. Measurements are obtained of deposition layer thickness after the chemical vapor deposition (CVD) process, and of the copper (or other metal) trench profile (depth, top critical dimension, bottom critical dimension, and/or other critical dimensions along the trench side-wall at any depth of interest, dishing, erosion) after the etch process. The trench profile measurements are used as feed forward information, together with the CVD measurement, in adjusting the removal rate at the CMP to leave an acceptable amount of metal material in the copper cross section, with copper being an example of the metal material. Thus, by measuring the post CVD thickness, the present invention can determine the appropriate point to which the CMP process should polish, and by measuring the post-etch trench, the area of metal at a corresponding plane in the trench (once polishing occurs to that point) can be determined, as then can the resistance.

For wafers already processed by CVD and etch devices, CMP utilizes the feed forward data to control the metal line cross-section area uniformity within wafer; whereas CVD and etch utilize the measurement results to adjust their own processes via feedback for the next wafer(s). In a similar manner, the in-line an/or integrated metrology at CMP also takes measurements post CMP process, and feeds the data back to CMP for both WIW and WTW control. In general, use of the present invention allows the wiring resistance variance to be reduced.

In accordance with at one or more embodiments of the present invention, in operation, there is provided a computer-implemented method, system, and computer program for controlling metal line resistance (RS) uniformity in a semiconductor manufacturing process using integrated or in-line metrology. The invention provides for collecting first data representative of at least one measurement of a first thickness of at least one deposition layer, subsequent to a deposition process on at least one semiconductor product. Further included is collecting second data representative of a plurality of measurements characterizing a profile of at least one trench in the at least one deposition layer, subsequent to an etch process on the at least one semiconductor product. Also included is collecting third data representative of at least one measurement of a second thickness of the at least one deposition layer, and a thickness of a metal deposited in the at least one trench, on the at least one semiconductor product. Further included is determining an area of a cross section of metal in the at least one trench at the profile and comparing the area to a target resistance. Also included is determining a planarization process to adjust an amount of metal in the at least one trench to approximate the target resistance in the at least one semiconductor product.

According to one or more embodiments of the present invention, the invention includes utilizing the determined planarization process for at least one of: the at least one semiconductor product, an other semiconductor product subsequent to the at least one semiconductor product, a lot of semiconductor products including the at least one semiconductor product, and a lot of semiconductor products including the other semiconductor product.

According to one or more embodiments of the present invention, also included is utilizing at least one of: the first data to adjust the deposition process, the second data to adjust a lithography process and/or the etch process, and the third data to adjust the planarization process.

According to one or more embodiments of the present invention, also included is determining a variation in resistance over a plurality of semiconductor products including the at least one semiconductor product.

One or more embodiments of the present invention provides that the at least one deposition layer includes a dielectric deposition layer, and the deposition process is a chemical vapor deposition process.

One or more embodiments of the present invention provides that the measurements characterizing the profile include at least depth, top critical dimension, bottom critical dimension, and at least one critical dimension along a side wall of the at least one trench.

According to one or more embodiments of the present invention, the third data includes data representative of a dishing and/or erosion of the method in the at least one trench and measurement of remaining thickness.

According to one or more embodiments of the present invention, the determined planarization process includes at least one of a removal rate, a polishing pressure, and chemical supplies to be used.

As such, those skilled in the art will appreciate that the conception, upon which this disclosure is based, may readily be utilized as a basis for the designing of other structures, methods and systems for carrying out the several purposes of the present invention. It is important, therefore, that the application be regarded as including such equivalent constructions insofar as they do not depart from the spirit and scope of the present invention.

### BRIEF DESCRIPTION OF THE SEVERAL VIEWS OF THE DRAWING(S)

The above mentioned and other advantages and features of the present invention will become more readily apparent from the following detailed description in the accompanying drawings, in which:

FIG. 1 is a cross section illustrating an example of a semiconductor wafer with trenches therein.

FIG. 2 is a block diagram of a computerized process control system that may be used in connection with one or more embodiments of the present invention.

FIG. 3 is a schematic representing layers in a cross-section of a semiconductor wafer, used in connection with one or more embodiments of the present invention.

FIG. 4 is a schematic representing measurements taken of a trench in a semiconductor wafer, in connection with one or more embodiments of the present invention.

FIG. 5 is a schematic representing measurements taken of metal in the trench in the semiconductor wafer of FIG. 4, in accordance with one or more embodiments of the present invention.

FIG. 6 is a diagram representing an example of measurements in trenches in a semiconductor wafer, in accordance with one or more embodiments of the present invention.

FIG. 7 is a graph illustrating simulated representative measurements of remaining film in a semiconductor wafer in comparison to total trench depth, in connection with one or more embodiments of the present invention.

FIG. 8 is a flow chart of a process for controlling resistance (RS) variance according to one or more embodiments of the present invention.

FIG. 9 is an illustration is a computer for use in implementing the computer processing in accordance with one or more embodiments of the present invention.

FIG. 10 is a block diagram illustrating the internal hardware of the computer of FIG. 9.

### DETAILED DESCRIPTION

The following detailed description includes many specific details. The inclusion of such details is for the purpose of illustration only and should not be understood to limit the invention. Throughout this discussion, similar elements are referred to by similar numbers in the various figures for ease of reference.

Resistance (Rs) is a quality used to define conductivity. Rs may be monitored and/or controlled by determining the amount of metal to be used for a given purpose and, with specific regard to semiconductor devices, by controlling the amount of metal deposited and/or removed in the process of creating the semiconductor device.

The amount of metal residing in the metal lines of a semiconductor device may not effectively be measured in a non-destructive manner at any one point during the process of manufacturing the device. Consequently, one or more embodiments of the present invention contemplate making appropriate measurements during the various steps involved in the process of creating the metal lines.

Rs of a metal line in a semiconductor is principally determined by two processes, the etch process and the chemical mechanical planarization (“CMP”) process. The etch process produces one or more trenches in the film, where the trenches will contain the metal. The geometry of the trench is thus determined by the etch process. The CMP process polishes and removes material such as the excess electro-chemical plating, used to fill in the trenches.

In one or more embodiments of the present invention, Rs may be monitored by utilizing measurements taken by three metrology tools. Specifically, the dielectric deposition metrology tool measures the film thickness, the etch metrology tool measures the trench profile and hence provides a characterization of the trench profile, and the CMP metrology tool, e.g., for copper, provides a measurement of metal loss (by measuring oxide loss and metal recess). Taking the shape of the trench profile and the depth and any dishing or erosion of the copper into consideration, the area of the metal in a cross section (ultimately indicating the volume of metal in the trench, generally) may be determined. Controlling the processing devices correlated to these metrology tools consequently provides a control over the resistance.

It should be understood that any number of different types of metrology tools may be used to obtain the necessary measurements, and may be in-line or integrated into the processing devices. Conveniently, some metrology tools conventionally measure and collect data including at least some of the required information.

Various process performance parameters may be collected, e.g., via inline metrology tools, to adequately characterize the area of the metal in a cross section of the metal line, and include: (1) thickness of the layer(s) to be etched, subsequent to deposition of that layer(s); (2) depth of the trench etched in the layer(s); (3) critical dimension of the bottom of the trench; (4) critical dimension of the top of the trench (as well as potentially at different depths); (5) amount of dishing and/or erosion of the metal in the trench subsequent to planarization; and/or (6) thickness of the layer(s) that were etched, subsequent to planarization. Additional and/or other parameters could be utilized to provide different characterizations of the cross section of the metal line, and/or to take into consideration other layers and/or geographies affecting the measurement of metal in the metal line(s).

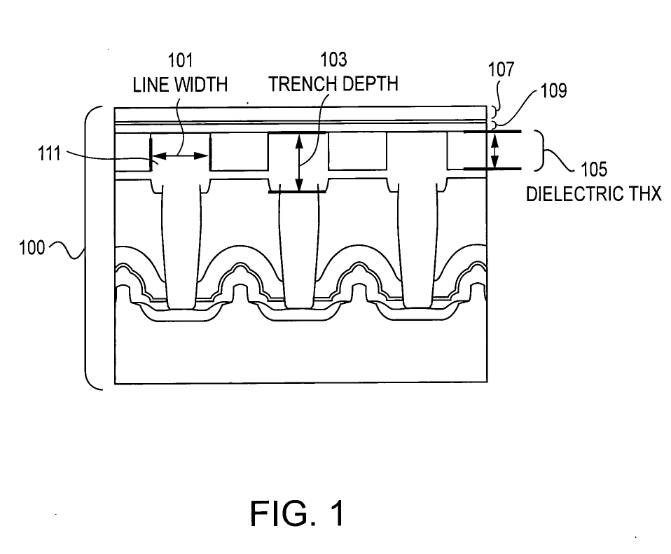

FIG. 1 illustrates an example cross section of a semiconductor wafer 100, with various layers used in manufacturing the wafer, and illustrating a cross section of a metal line 111. Referring now to FIG. 1, shown are the metal line width 101, metal line trench depth 103, dielectric layer thickness 105, top film 107 (having a thickness), and metal layer 109, which may be used in calculating an area of the cross section of the metal line. All of these measurements are difficult to obtain at a single point in time during the semiconductor device manufacturing process.

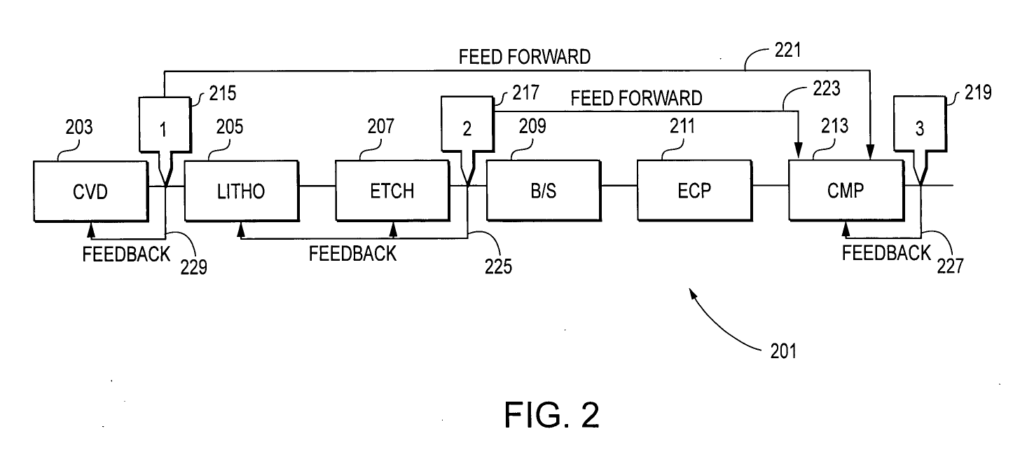

Reference is now made to FIG. 2, a block diagram generally illustrating a computerized semiconductor device manufacturing system 201 that may be used in connection with at least some embodiments of the present invention. FIG. 2 illustrates, inter alia, multiple feed forwards and multiple feedbacks of information. The diagram also illustrates specific processes that may be used to create a semiconductor device, including for example chemical vapor deposition (CVD) 203, lithography (“litho”) 205, etch 207, barrier seed (B/S) 209, electrico-chemical plating (ECP) 211, and chemical mechanical planarization (CMP) 213. In the present illustration, metrology tools are positioned at the measured process, e.g., a metrology tool 215 is provided for CVD. The semiconductor manufacturing process may provide metrology tools for other processing devices, e.g., B/S and ECP; however, these are omitted for simplicity of illustration. Further, some or all of the information that may be developed from those particular processing devices may be omitted in operation of one or more embodiments of the present invention.

Reference is now made to blocks 215, 217, 219, illustrating metrology tools 215, 217, 219 taking measurements of processed wafers subsequent to the processing for CVD 203, etch 207, and CMP 213, respectively. The CVD measurements are used in a feed forward 221 to the CMP process 213, and the etch measurements also are used in a feed forward to the CMP process. Equation (1) (below) is an example feedforward calculation utilizing t_{cvd}, the measured thickness information obtained about the wafer from the CVD metrology tool 215 subsequent to the wafer having passed through the CVD process 203. Further, measurements from processing for CVD, etch and CMP are used in feedback 229, 225, 227 to themselves.

The example also illustrates process blocks for litho 205, B/S 209, and ECP 211, as parts of one example of a conventional process. These and/or other measurements may be taken by certain implementations of a device manufacturing process.

In general, it should be understood that various embodiments of the present invention contemplate utilizing various combinations of the processes and associated mechanisms mentioned above, as well as fewer or additional processes and/or mechanisms as would be apparent to one skilled in the art.

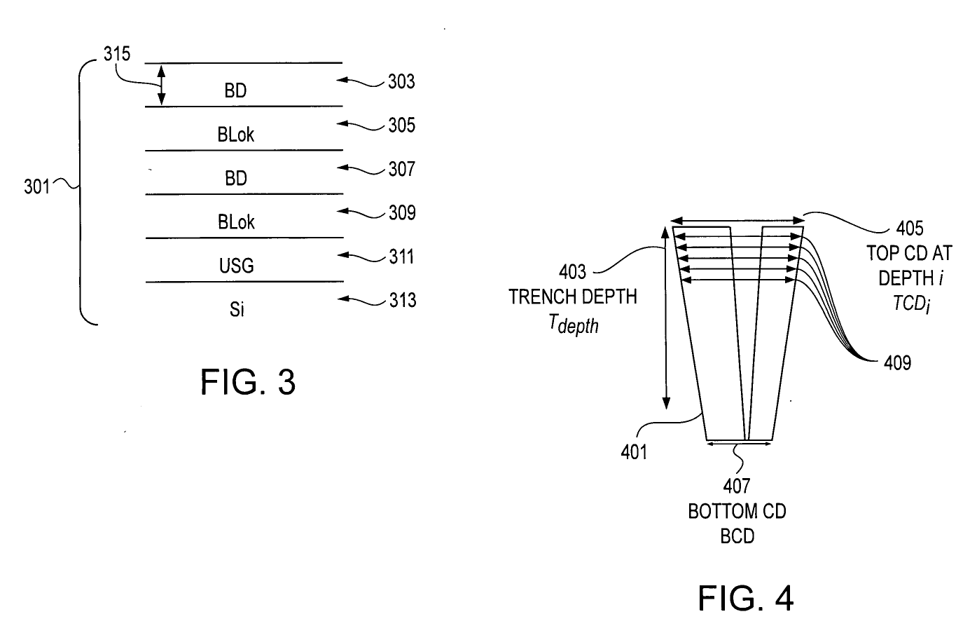

Reference is now made to FIG. 2 in conjunction with FIG. 3, illustrating the CVD 203 process. FIG. 3 illustrates a number of layers, e.g., Black Diamond™ low k dielectric 303 (BD), 307, barrier low K (BLoK) process films 305, 309, undoped silicate glass (USG) 311, and silicon (Si) 313 in an example wafer 301 that is being processed by the computerized process control system 201. (There are many suitable alternatives to the BD and BloK process films).

In a first step, the CVD has deposited the last layer of BD. A metrology tool may be used to measure the thickness 315 of the BD. The tool is illustrated as being in-line, but may be, e.g., integrated. The measured BD thickness 315 information is used locally in a feedback 229 to the CVD process 203, e.g., so that the next wafer's thickness will be adjusted to meet a target thickness. The measured thickness information obtained from the CVD (“t_{cvd}”) also is utilized in a feed forward 221, for example to the CMP, and/or to a processor making feed forward calculations and controlling the CMP.

Reference is now made to FIG. 2 in conjunction with FIG. 4, relating to the etch process 207 and the etch metrology tool 217. After the CVD process 203, conventional litho and etch processes are performed in order to, inter alia, form trenches preparatory to the formation of metal lines in the semiconductor device. Subsequent to the etch process 207, information is collected, including data characterizing measurements of the trench profile. FIG. 4 represents an example trench 401 having a typical trapezoid profile, although not necessarily to scale for illustration purposes. The profile may include more or less of a sidewall angle than shown in this illustration. In this example, another metrology tool 217 is used subsequent to the etch process 207 to obtain, e.g., three numbers from this single measurement in order to characterize the trench profile: trench depth (“T_{depth}”) 403, trench bottom critical dimension (“BCD”) 407, and top critical dimension at depth i (“TCDᵢ”) 405 (where i=0). The TCDᵢ (where i=0) may be, e.g., 500 angstroms. Critical dimension at other depths i (where I is a number other than 0) may be collected at one or more depths i, and such collected information may be utilized in connection with one or more embodiments of the present invention. Of course, it should be understood that one or more numbers from these and/or other measurements can also be used to characterize the trench profile.

Information characterizing one or more additional layers may be collected as well, for example, the thickness of a subsequent dielectric antireflective coating (DARC) layer. It may be desirable to adjust different layers appropriately, taking into consideration their own properties. Additional control may be achieved by considering additional layers and their properties, e.g., the removal rate of DARC in response to various CMP parameters. For example, by obtaining the measurement of the remaining DARC thickness subsequent to the BD, the CMP process may better control, e.g., the time parameters at a given platen, in order to minimize undesirable metal recess.

The information collected by the etch metrology tool 217 may be locally fed back 225 for conventional use in adjusting the etch processing 207 and/or the litho processing 205.

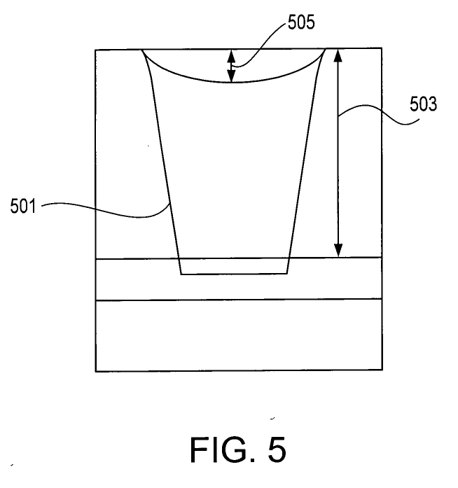

Reference is now made to FIG. 2 in conjunction with FIG. 5, illustrating a measurement taken by the CMP metrology tool 219 after the CMP process 213. At the CMP stage, measurements are taken of the trench 501 of information to assist in characterizing oxide loss, dishing and/or erosion. A measured property may be, e.g., metal dishing 505. Another property that may be measured is BD thickness 503 (t_{cmp}), that is, the thickness in the top layer remaining after CMP processing. (Black Diamond™ is one example of several appropriate low k dielectrics that may be used for the top layer.)

Any of these measurements may be obtained from a direct measurement if possible, or alternatively may be calculated based on other measurements. For example, metal dishing 505 may be determined to be the difference in height between the measured lowest point of a copper line/bond pad (typically at the center of the structure) and the measured height of the surrounding film.

The following equation (1) is an example calculation for determining the area of the cross section of the metal line, in this case copper:
Cu_Area=1/2{T_{depth}−[(t_{cvd}−t_{cmp})+Dₘₑₜₐₗ]}*(TCDᵢ+BCD) (1)

Where

T_{depth} is measured trench depth;

t_{cvd} is measured thickness of the deposited top layer, e.g., from the CVD metrology tool;

t_{cmp} is measured thickness of the polished top layer, e.g., from the CMP metrology tool;

Dₘₑₜₐₗ is measured dishing of the metal, e.g., from the CMP metrology tool;

TCDᵢ+ is top critical dimension of the trench measured at depth I; and

BCD is bottom critical dimension of the trench measured at the trench bottom.

It will be appreciated by one of skill in the art that other calculations may be utilized in order to approximate the area of a cross section of the metal line. For example, if the geometry of the trench is not evenly trapezoidal, a different calculation may be composed and used. As another example, a closer approximation of the effect of dishing may be utilized.

Measurements of multiple points on each wafer are collected at each of the various metrology tools. The location of measured points is identified. Typically, a measurement location is identified with X,Y coordinates referenced to a wafer center as well as a die corner, coordinates referencing a die, and a die location referenced by column and row. The coordinates are a convenient way to match corresponding measurements for the same (or a sufficiently close) point on a wafer, for measurements collected at the different metrology tools. Typically the system considers the pattern of the semiconductor product and determines where to measure for all the processes.

Nevertheless, it might not always be practical to measure precisely the same location. Within, e.g., 5 mm in radius, the film/surface of the chip usually is sufficiently uniform, except perhaps chip edges. Most processes exhibit concentric effects, so that measurements along a diameter with, e.g., 5 mm edge exclusion and total 13 data points (for a 300 mm wafer) or 9 data points (for a 200 mm wafer) are sufficient. Alternatives include, e.g., taking measurements in either 2 dimensions, or in multiple directions.

In one or more embodiments of the present invention, Rs control is provided via both within wafer and wafer-to-wafer control. The goals of Rs control may include obtaining a more uniform copper cross section area within a wafer; and obtaining a more consistent copper cross section area from wafer to wafer. To that end, the etch process may be used to control the trench depth and width, such as via local feedback. The CMP process may be used to control the thickness of the layer(s) in which the trench is etched and/or to control dishing, via local feedback and/or data fed forward from the etch process. In the case of uniform trench profile within wafer and wafer to wafer, the CMP process controls its own metal loss to its uniformity specification. In a situation where the trench profile varies within wafer, the CMP acts according to the trench profile and location in concentric zones.

The CMP process may be adjusted according to known processes. Conventionally, there are two principal components in controlling total metal loss at the CMP: global dielectric loss and metal recess. The former is mainly due to mechanical polishing, so it may be controlled by adjusting down force at the CMP. The latter is due to both mechanical and chemical effects; usually chemical effects are adjusted via controlling or balancing dielectric and metal removal rates.

The process control system may provide the conventional local feedback at each stage, for example: CVD feedback to itself 229, etch feedback to itself 225, and CMP feedback to itself 227. Also illustrated in FIG. 2 (as indicated previously) are feed forward mechanisms 221, 223 for forwarding metrology information to the CMP process 213. The use of feedback and feed forward allows within wafer control as well as wafer-to-wafer control. Hence, the system provides for within wafer control, and wafer-to-wafer control. One or more embodiments of the present invention further contemplate lot-to-lot control, where e.g. process performance is sufficiently uniform for wafers within a lot.

As indicated in the example of FIG. 2, the process control system performs a feedforward function, e.g., feedforward 221 from the CVD process 203 to the CMP process 213, CVD being an initial deposition. If the CVD process 203, for example, normally puts down 5,000 angstroms of film, and after the CMP process only 3,000 angstroms of film are left, then about 2,000 angstroms were lost. That loss partially corresponds to the total metal loss, since metal is etched from the surface down inside the BD layer. By considering the metal starting surface (after CVD) to be the same as the original BD thickness, taking into consideration the loss measured after CMP, then 2,000 angstroms of metal were also removed.

Furthermore, there may exist a metal dishing and/or erosion inside the line at the CMP, which varies depending on various process parameters, e.g., wafer pressure and platen speed. The dishing makes a contribution to the total metal loss. These process parameters may be adjusted at the CMP.

In summary, by collecting information characterizing the measurements comprising the trench profile and metal (e.g., copper) topography, the present invention may estimate or otherwise calculate what the cross section of the metal line looks like. The different measurements utilized to perform this calculation are collected at different processing system locations. Also, the measurements may be collected for multiple locations on multiple lines. Based on the calculated area of the metal line, the system may then adjust the processing at one or more points of the overall semiconductor device manufacturing system accordingly, in order to increase uniformity and/or conformance to the desired standard.

In order to perform a wafer-to-wafer adjustment, for example the system measures a specific wafer with a metrology tool subsequent to the CVD process 203, and that particular wafer is adjusted when it goes through the CMP process 213. For example, consider that the incoming thickness differs from the expected incoming thickness, whether it is 5,000 angstroms or 500. Considering that the process tends to be about the same for a given series of wafers, feedback may be used to adjust processing wafer-to-wafer. Feed forward may be used to adjust processing downstream for within the same wafer. As another example, if the measurement subsequent to the etch step is also different from what is expected, then an adjustment may be made to the CMP process 213 to adjust the removal rate so as to leave the correct amount of material.

To illustrate a wafer-to-wafer adjustment using local feedback, consider for example processing a batch of wafers through the CVD after which they are measured with the metrology tool. If the first wafer measures 4,900 angstroms, it is 100 angstroms away from the target of 5,000 angstroms. When the system performs CVD deposit on the next wafer, the process parameter is adjusted utilizing this feedback so that it will deposit an additional 100 angstroms.

Appropriate inline metrology tools can include, for example a reflectometry or ellipsometry metrology tool for measuring post-CVD; a scatterometry metrology tool for measuring post-etch; and a reflectometry interferometry metrology tool for measuring post-CMP.

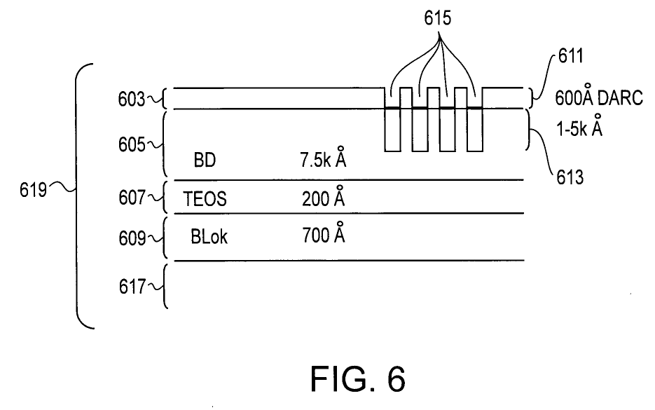

Reference is now made to FIG. 6, an illustration of a semiconductor wafer profile 619 where an example semiconductor device is described to provide a more precise example. The semiconductor device as indicated by profile 619 has a bottom layer 617 of a substrate, a BLok layer 609 measuring 700 angstroms, a TEOS layer 607 measuring 200 angstroms, a BD layer 605 measuring 7,500 angstroms, and an optional DARC layer 603 measuring 600 angstroms. Trenches 615 have been etched through the DARC and ending in the BD layer 603, 605. The DARC layer 603 thickness 611, measured subsequent to the etch processing, may be fed forward to the processor controlling the CMP processing. The DARC layer thickness then may be used to control the CMP processing, e.g. for control of a specific platen polishing time. The amount of DARC thickness remaining may be ascertained from measuring trench depth 615, 601.

For different processes, the DARC thickness remaining before the processing may be different. Where the information is unavailable, the polishing at the CMP, e.g., at a platen, may be estimated based on the DARC thickness deposited during the CVD processing, which may be different from the true value.

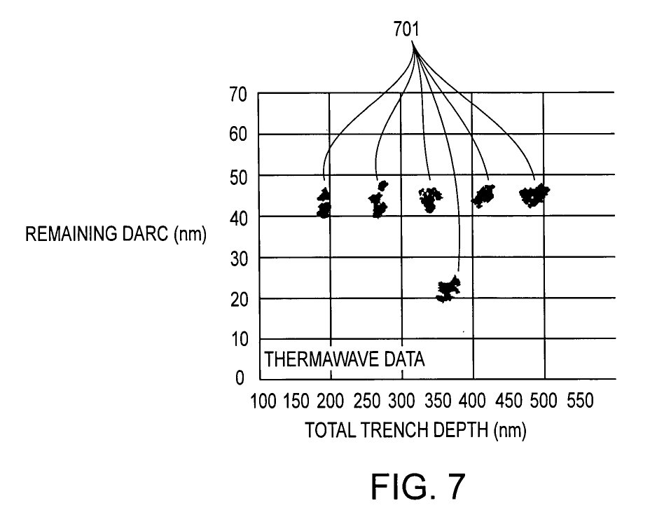

Reference is now made to FIG. 7, illustrating total trench depth (in nm) compared to the thickness of the DARC (in nm) remaining after processing, as measured by a scatterometry metrology tool. Values from an actual test using an experimental setup of approximately six wafers are illustrated. As shown in this example, the measurements obtained of remaining DARC are fairly non-dispersed. This shows the improved control over trench measurements, and hence control over trench profile, yielding improved control over metal lines, metal resistance and deviation.

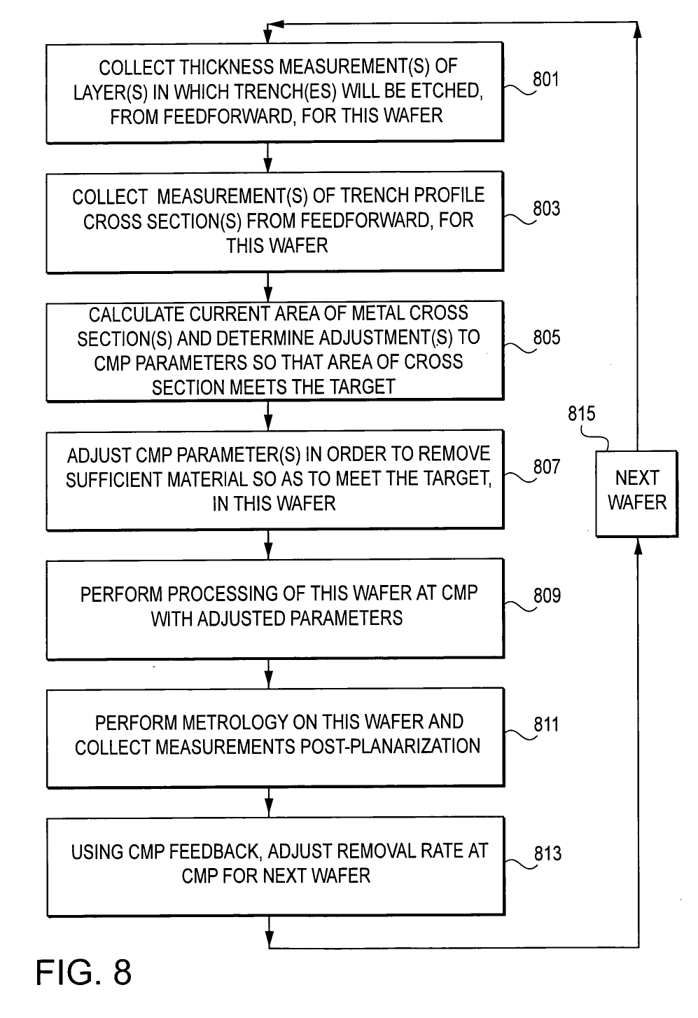

Reference is now made to FIG. 8, a flow chart of a process for controlling resistance (RS) in a metal line according to one or more embodiments of the present invention. Consider in this particular example that the CMP processing includes an integrated automatic process control feature, so that the processing to control the CMP is, in effect, embedded into the CMP. At block 801, the processor collects the thickness measurement(s) of one or more layer(s) in which one or more trenches will be etched, in the present wafer; these measurements have been fed forward from the post-CVD metrology tool. At block 803, the processor collects the measurement(s) characterizing the profile(s) of the trench cross-section(s), in the present wafer; again, these measurements have been fed forward from the post-etch metrology tool. At block 805, the processor calculates the current area of the cross section(s) of the metal line(s), using the feedforward measurements for this wafer. The various trenches may have different profiles. The processor determines one or more adjustments to the CMP parameters controlling the CMP processing, so that the area of the cross section of the line meets a pre-defined target for the line. (Different lines may have different targets.) At block 807, the processor adjusts the CMP parameter(s) in order to remove a sufficient amount of material so as to meet the target, when processing the present wafer. At block 809, the CMP performs processing of the present wafer utilizing the adjusted parameters. At block 811, CMP processing has been completed and the post-CMP metrology tool performs metrology on the present wafer and collects various measurements characterizing, inter alia, the remaining thickness of material. At block 813, the processor receives feedback (from the measurements of block 811), and performs a conventional adjustment of the removal rate at the CMP in preparation for the next wafer. At block 815, the processor is prepared for the next wafer. In one or more embodiments, a processor (either internal or external to the CMP) may control some or all of the manufacturing processes, such as those shown in FIG. 2.

By receiving information characterizing deposition thickness uniformity (within the same wafer) and post-CMP processing BD thickness, the CMP may control its dielectric loss within wafer, wafer-to-wafer, and/or lot-to-lot. Further, by receiving information characterizing a variation among trench profiles within a wafer, where the profile variation is centric, the CMP can control by concentric zones within the wafer, to tolerances within CMP specification limits.

One or more embodiments of the present invention provide for measuring of the RS subsequent to processing, and for further determination of whether the actual RS is sufficiently close to the target RS. The RS measurement may be made off-line, such as by an e-tester tool available from, e.g. QuadTech, or in line if an appropriate tool is available. One or more embodiments of the present invention provide that the actual RS is compared to the calculated RS (as determined by the measurements) and/or the target RS.

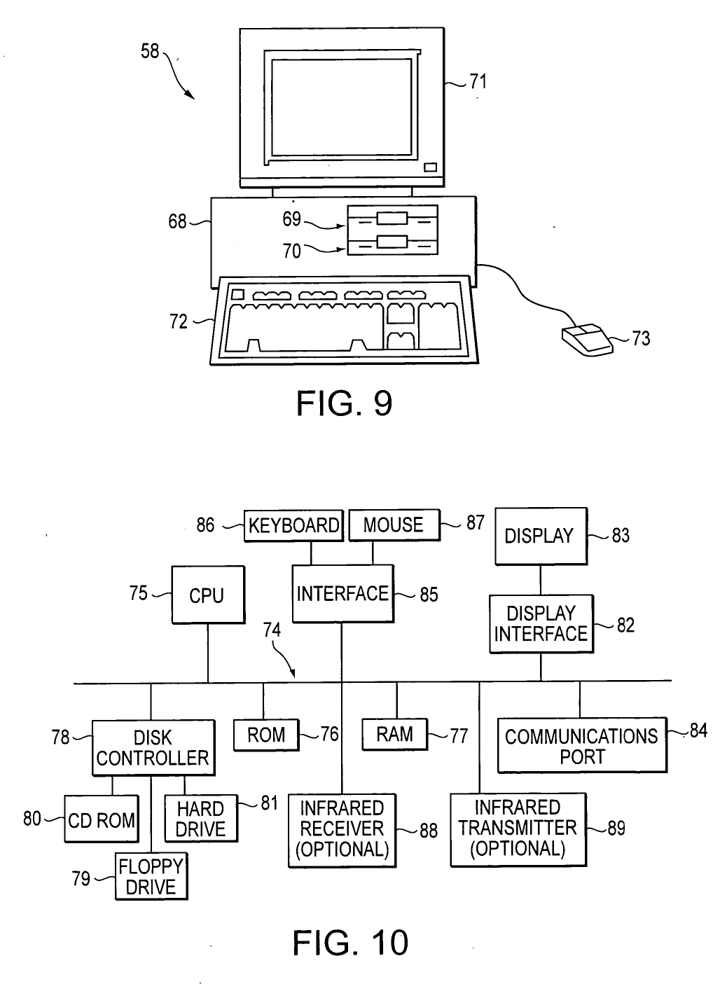

FIG. 9 is an illustration of a computer 58 used for implementing the computer processing in accordance with a computer-implemented embodiment of the present invention. The procedures described above may be presented in terms of program procedures executed on, for example, a computer or network of computers.

Viewed externally in FIG. 9, computer 58 has a central processing unit (CPU) 68 having disk drives 69, 70. Disk drives 69, 70 are merely symbolic of a number of disk drives that might be accommodated by computer 58. Typically, these might be one or more of the following: a floppy disk drive 69, a hard disk drive (not shown), and a CD ROM or digital video disk, as indicated by the slot at 70. The number and type of drives varies, typically with different computer configurations. Disk drives 69, 70 are, in fact, options, and for space considerations, may be omitted from the computer system used in conjunction with the processes described herein.

Computer 58 also has a display 71 upon which information may be displayed. The display is optional for the computer used in conjunction with the system described herein. A keyboard 72 and/or a pointing device 73, such as a mouse 73, may be provided as input devices to interface with central processing unit 68. To increase input efficiency, keyboard 72 may be supplemented or replaced with a scanner, card reader, or other data input device. The pointing device 73 may be a mouse, touch pad control device, track ball device, or any other type of pointing device.

FIG. 10 illustrates a block diagram of the internal hardware of the computer of FIG. 9. CPU 75 is the central processing unit of the system, performing calculations and logic operations required to execute a program. Read only memory (ROM) 76 and random access memory (RAM) 77 constitute the main memory of the computer. Disk controller 78 interfaces one or more disk drives to the system bus 74. These disk drives may be floppy disk drives such as 79, or CD ROM or DVD (digital video/versatile disk) drives, as at 80, or internal or external hard drives 81. As previously indicated these various disk drives and disk controllers are optional devices.

A display interface 82 permits information from bus 74 to be displayed on the display 83. Again, as indicated, the display 83 is an optional accessory for a central or remote computer in the communication network, as are infrared receiver 88 and transmitter 89. Communication with external devices occurs using communications port 84.

In addition to the standard components of the computer, the computer may also include an interface 85, which allows for data input through the keyboard 86 or pointing device, such as a mouse 87.

While this invention has been described in conjunction with the specific embodiments outlined above, many alternatives, modifications and variations will be apparent to those skilled in the art. Accordingly, the preferred embodiments of the invention as set forth are intended to be illustrative and not limiting. Various changes may be made without departing from the spirit and scope of the invention as defined in the application. The foregoing detailed description includes many specific details. The inclusion of such detail is for the purpose of illustration only and should not be understood to limit the invention. In addition, features in one embodiment may be combined with features in other embodiments of the invention. Various changes may be made without departing from the scope of the invention as defined in the application.

As an example, the invention has been discussed in connection with metal structures involved in creating a second level of a multi-level semiconductor device, e.g., metal level 2 structures. The principles are applicable to all metal levels, including, e.g., metal level 1. According to one or more embodiments of the present invention, the processes may be repeated for one or more levels in a multiple-level semiconductor device.

As another example, the system may be a factory automation system with a general purpose computer, or a specially programmed special purpose computer. It may also be implemented to include a distributed computer system rather than as a single computer; some of the distributed system might include embedded systems. Further, the programming may be distributed among processing devices and metrology tools and/or other parts of the process control system. Similarly, the processing could be controlled by a software program on one or more computer systems or processors, or could be partially or wholly implemented in hardware. Moreover, the factory automation system may communicate directly or indirectly with the relevant metrology tool(s), processing device(s), and metrology system(s); or the metrology tool(s), processing device(s) and metrology system(s) may communicate directly or indirectly with each other and the factory automation system.

As another example, the system may be implemented on a web based computer, e.g., via an interface to collect and/or analyze data from many sources. It may be connected over a network, e.g., the Internet, an Intranet, or even on a single computer system. Moreover, portions of the system may be distributed (or not) over one or more computers, and some functions may be distributed to other hardware, such as tools, and still remain within the scope of this invention. The user may interact with the system via e.g., a personal computer or over PDA, e.g., the Internet, an intranet, etc. Either of these may be implemented as a distributed computer system rather than a single computer. Similarly, a communications link may be a dedicated link, a modem over a POTS line, and/or any other method of communicating between computers and/or users. Moreover, the processing could be controlled by a software program on one or more computer systems or processors, or could even be partially or wholly implemented in hardware.

User interfaces may be developed in connection with an HTML display format. It is possible to utilize alternative technology for displaying information, obtaining user instructions and for providing user interfaces.

The invention has been discussed in connection with particular examples. However, the principles apply equally to other examples and/or realizations. For example, BD and BloK process films were discussed, although the invention may be performed in connection with other films in a semiconductor chip. Naturally, the relevant data may differ, as appropriate, and as would be apparent to one skilled in the art.

The system used in connection with the invention may rely on the integration of various components including, as appropriate and/or if desired, hardware and software servers, database engines, and/or other process control components. The configuration may be, alternatively, network-based and may, if desired, use the Internet as an interface with the user.

The system according to one or more embodiments of the invention may store collected information in a database. An appropriate database may be on a standard server, for example, a small Sun™ Sparc™ or other remote location. The information may, for example, optionally be stored on a platform that may, for example, be UNIX-based. The various databases maybe in, for example, a UNIX format, but other standard data formats may be used.

Although the process control system is illustrated as having a single computer, the system according to one or more embodiments of the invention is optionally suitably equipped with a multitude or combination of processors or storage devices. For example, the computer may be replaced by, or combined with, any suitable processing system operative in accordance with the principles of embodiments of the present invention, including sophisticated calculators, hand held, laptop/notebook, mini, mainframe and super computers, one or more embedded processors, as well as processing system network combinations of the same. Further, portions of the system may be provided in any appropriate electronic format, including, for example, provided over a communication line as electronic signals, provided on floppy disk, provided on CD Rom, provided on optical disk memory, etc.

Any presently available or future developed computer software language and/or hardware components can be employed in such embodiments of the present invention. For example, at least some of the functionality mentioned above could be implemented using Visual Basic, C, C++ or any assembly language appropriate in view of the processor being used. It could also be written in an interpretive environment such as Java and transported to multiple destinations to various users.

The invention may include a process and/or steps. Where steps are indicated, they may be performed in any order, unless expressly and necessarily limited to a particular order. Steps that are not so limited may be performed in any order.

The many features and advantages of the embodiments of the present invention are apparent from the detailed specification, and thus, it is intended by the application to cover all such features and advantages of the invention that fall within the true spirit and scope of the invention. Further, since numerous modifications and variations will readily occurred to those skilled in the art, it is not desired to limit the invention to the exact construction and operation illustrated and described, and accordingly, all suitable modifications and equivalents maybe resorted to, falling within the scope of the invention.

1. A computer-implemented method for controlling metal line resistance (RS) uniformity in a semiconductor manufacturing process using integrated or in-line metrology, comprising the steps of:
(A) collecting first data representative of at least one measurement of a first thickness of at least one deposition layer, subsequent to a deposition process on at least one semiconductor product;
(B) collecting second data representative of a plurality of measurements characterizing a profile of at least one trench in the at least one deposition layer, subsequent to an etch process on the at least one semiconductor product;
(C) collecting third data representative of at least one measurement of a second thickness of the at least one deposition layer, and a thickness of a metal deposited in the at least one trench, on the at least one semiconductor product;
(D) determining an area of a cross section of metal in the at least one trench at the profile and comparing the resistance of the area to a target resistance; and
(E) determining a planarization process to adjust an amount of metal in the at least one trench to approximate the target resistance in the at least one semiconductor product.

2. The method of claim 1, further comprising utilizing the determined planarization process for at least one of: the at least one semiconductor product, another semiconductor product subsequent to the at least one semiconductor product, a lot of semiconductor products including the at least one semiconductor product, and a lot of semiconductor products including the other semiconductor product.

3. The method of claim 1, further comprising utilizing at least one of: the first data to adjust the deposition process, the second data to adjust a lithography process and/or the etch process, and the third data to adjust the planarization process.

4. The method of claim 1, further comprising determining a variation in resistance over a plurality of semiconductor products including the at least one semiconductor product.

5. The method of claim 1, wherein the at least one deposition layer includes a dielectric deposition layer, and wherein the deposition process is a chemical vapor deposition process.

6. The method of claim 1, wherein the plurality of measurements characterizing the profile include at least depth, top critical dimension, bottom critical dimension, and at least one critical dimension along a side wall of the at least one trench.

7. The method of claim 1, wherein the third data includes data representative of a dishing and/or erosion of the method in the at least one trench.

8. The method of claim 1, wherein the determined planarization process includes at least one of a removal rate, a polishing pressure, and chemical supplies to be used.

9. The method of claim 1, further comprising the step of measuring the actual resistance of metal in the at least one trench, and comprising the actual resistance to the target resistance.

10. A computer-implemented method for improving and controlling metal line resistance (RS) uniformity in a semiconductor manufacturing process using integrated or in-line metrology, comprising the steps of:
(A) collecting first data representative of at least one measurement of a first thickness of at least one dielectric deposition layer, subsequent to a chemical vapor deposition process on at least one semiconductor product;
(B) collecting second data representative of a plurality of measurements characterizing a profile of at least one trench in the at least one dielectric deposition layer, including at least depth, top critical dimension, bottom critical dimension, and at least one critical dimension along a side wall, of the at least one trench, subsequent to an etch process on the at least one semiconductor product;
(C) collecting third data representative of at least one measurement of a second thickness of the at least one dielectric deposition layer, a thickness of a metal deposited in the at least one trench, and a dishing and/or erosion of the metal in the at least one trench, on the at least one semiconductor product;
(D) determining an area of a cross section of metal in the at least one trench at the profile, and comparing the resistance of the area to a target resistance;
(E) determining at least one of a removal rate, polishing pressure, and chemical supplies to use in the chemical mechanical planarization process, to leave an amount of metal in the at least one trench, approximating the target resistance in the at least one semiconductor product;
(F) utilizing the at least one of the determined removal rate, polishing pressure, and chemical supplies in the chemical mechanical planarization process for at least one of: the at least one semiconductor product, another semiconductor product subsequent to the at least one semiconductor product, a lot of semiconductor products including the at least one semiconductor product, and a lot of semiconductor products including the other semiconductor product;
(G) utilizing at least one of: the first data to adjust the CVD process, the second data to adjust the litho and etch process, and the third data to adjust the CMP process, for the other semiconductor product subsequent to the at least one semiconductor product; and
(H) determining a variation in resistance over the plurality of semiconductor products including the at least one semiconductor product.

11. A computer-assisted system for controlling metal line resistance (RS) uniformity, in a semiconductor manufacturing process using integrated or in-line metrology components, comprising:
(A) at least one first component, to collect first data representative of at least one measurement of a first thickness of at least one deposition layer, subsequent to a deposition process on at least one semiconductor product;
(B) at least one second component, to collect second data representative of a plurality of measurements characterizing a profile of at least one trench in the at least one deposition layer, subsequent to an etch process on the at least one semiconductor product;
(C) at least one third component, to collect third data representative of at least one measurement of a second thickness of the at least one deposition layer, and a thickness of a metal deposited in the at least one trench, on the at least one semiconductor product; and
(D) at least one controller, communicating with the at least one first component, the at least one second component, and the at least one third component, to determine an area of a cross section of metal in the at least one trench at the profile, and to compare the resistance of the area to a target resistance; and to determine a planarization process, so as to leave an amount of metal in the at least one trench, approximating the target resistance in the at least one semiconductor product.

12. The system of claim 11, wherein the at least one controller utilizes the determined planarization process for at least one of: the at least one semiconductor product, another semiconductor product subsequent to the at least one semiconductor product, a lot of semiconductor products including the at least one semiconductor product, and a lot of semiconductor products including the other semiconductor product.

13. The system of claim 11, wherein the deposition process, responsive to the first data, adjusts the deposition process; a lithography process and/or the etch process, responsive to the the second data, adjusts the lithography process and/or the etch process; and the planarization process, responsive to the third data, adjusts the planarization process.

14. The system of claim 11, wherein the at least one controller determines a variation in resistance over a plurality of semiconductor products including the at least one semiconductor product.

15. The system of claim 11, wherein the at least one deposition layer includes a dielectric deposition layer, and wherein the deposition process is a chemical vapor deposition process.

16. The system of claim 11, wherein the plurality of measurements characterizing the profile include at least depth, top critical dimension, bottom critical dimension, and at least one critical dimension along a side wall of the at least one trench.

17. The system of claim 11, wherein the third data includes data representative of a dishing and/or erosion of the method in the at least one trench.

18. The system of claim 11, wherein the determined planarization process includes at least one of a removal rate, a polishing pressure, and chemical supplies to be used.

19. The system of claim 11, wherein the actual resistance of the metal in the at least one trench is measured and compared to the target resistance.

20. A computer-assisted system for controlling metal line resistance (RS) uniformity, in a semiconductor manufacturing process using integrated or in-line metrology, comprising:
(A) at least one first component, to collect first data representative of at least one measurement of a first thickness of at least one dielectric deposition layer, subsequent to a chemical vapor deposition process on at least one semiconductor product;
(B) at least one second component, to collect second data representative of a plurality of measurements characterizing a profile of at least one trench in the at least one dielectric deposition layer, including at least depth, top critical dimension, bottom critical dimension, and at least one critical dimension along a side wall, of the at least one trench, subsequent to an etch process on the at least one semiconductor product;
(C) at least one third component, to collect third data representative of at least one measurement of a second thickness of the at least one dielectric deposition layer, a thickness of a metal deposited in the at least one trench, and a dishing and/or erosion of the metal in the at least one trench, on the at least one semiconductor product;
(D) at least one controller, to determine an area of a cross section of metal in the at least one trench at the profile and to compare the resistance of the area to a target resistance; and to determine at least one of a removal rate, polishing pressure, and chemical supplies to use in the chemical mechanical planarization process, to leave an amount of metal in the at least one trench, approximating the target resistance in the at least one semiconductor product;
(E) wherein the at least one controller utilizes the at least one of the determined removal rate, polishing pressure, and chemical supplies in the chemical mechanical planarization process for at least one of: the at least one semiconductor product, another semiconductor product subsequent to the at least one semiconductor product, a lot of semiconductor products including the at least one semiconductor product, and a lot of semiconductor products including the other semiconductor product;
(F) wherein the deposition process, responsive to the first data, adjusts the deposition process; a lithograph process and/or the etch process, responsive to the second data, adjusts the lithography process and/or the etch process; and the planarization process, responsive to the third data, adjusts the planarization process; and
(G) wherein the at least one controller determines a variation in resistance over the plurality of semiconductor products including the at least one semiconductor product.

21. A computer program for controlling metal line resistance (RS) uniformity, in a semiconductor manufacturing process using integrated or in-line metrology, the computer program having instructions stored on at least one computer-readable medium, comprising:
(A) instructions for collecting first data representative of at least one measurement of a first thickness of at least one deposition layer, subsequent to a deposition process on at least one semiconductor product;
(B) instructions for collecting second data representative of a plurality of measurements characterizing a profile of at least one trench in the at least one deposition layer, subsequent to an etch process on the at least one semiconductor product;
(C) instructions for collecting third data representative of at least one measurement of a second thickness of the at least one deposition layer, and a thickness of a metal deposited in the at least one trench, on the at least one semiconductor product;
(D) instructions, on the computer-readable medium, for determining an area of a cross section of metal in the at least one trench at the profile and for comparing the resistance of the area to a target resistance; and
(E) instructions for determining a planarization process, so as to leave an amount of metal in the at least one trench, approximating the target resistance in the at least one semiconductor product.

22. The computer program of claim 21, further comprising instructions for utilizing the determined planarization process for at least one of: the at least one semiconductor product, another semiconductor product subsequent to the at least one semiconductor product, a lot of semiconductor products including the at least one semiconductor product, and a lot of semiconductor products including the other semiconductor product.

23. The computer program of claim 21, further comprising instructions for utilizing at least one of: the first data to adjust the deposition process, the second data to adjust a lithography process and/or the etch process, and the third data to adjust the planarization process, for the other semiconductor product subsequent to the at least one semiconductor product.

24. The computer program of claim 21, further comprising instructions for determining a variation in resistance over a plurality of semiconductor products including the at least one semiconductor product.

25. The computer program of claim 21, wherein the at least one deposition layer includes a dielectric deposition layer, and wherein the deposition process is a chemical vapor deposition process.

26. The computer program of claim 21, wherein the plurality of measurements characterizing the profile include at least depth, top critical dimension, bottom critical dimension, and at least one critical dimension along a side wall of the at least one trench.

27. The computer program of claim 21, wherein the third data includes data representative of a dishing and/or erosion of the method in the at least one trench.

28. The computer program of claim 21, wherein the determined planarization process includes at least one of a removal rate, a polishing pressure, and chemical supplies to be used.

29. The computer program of claim 21, further comprising instructions for measuring the actual resistance of metal in the at least one trench, and comparing the actual resistance to the target resistance.

30. A computer program for controlling metal line resistance (RS) uniformity, in a semiconductor manufacturing process using integrated or in-line metrology, the computer program stored on at least one computer-readable medium, comprising:
(A) instructions for collecting first data representative of at least one measurement of a first thickness of at least one dielectric deposition layer, subsequent to a chemical vapor deposition process on at least one semiconductor product;
(B) instructions for collecting second data representative of a plurality of measurements characterizing a profile of at least one trench in the at least one dielectric deposition layer, including at least depth, top critical dimension, bottom critical dimension, and at least one critical dimension along a side wall, of the at least one trench, subsequent to an etch process on the at least one semiconductor product;
(C) instructions for collecting third data representative of at least one measurement of a second thickness of the at least one dielectric deposition layer, a thickness of a metal deposited in the at least one trench, and a dishing and/or erosion of the metal in the at least one trench, on the at least one semiconductor product;
(D) instructions for determining an area of a cross section of metal in the at least one trench at the profile and for comparing the resistance of the area to a target resistance;
(E) instructions for determining at least one of a removal rate, polishing pressure, and chemical supplies to use in the chemical mechanical planarization process, to leave an amount of metal in the at least one trench, approximating the target resistance in the at least one semiconductor product;
(F) instructions for utilizing the at least one of the determined removal rate, polishing pressure, and chemical supplies in the chemical mechanical planarization process for at least one of: the at least one semiconductor product, another semiconductor product subsequent to the at least one semiconductor product, a lot of semiconductor products including the at least one semiconductor product, and a lot of semiconductor products including the other semiconductor product;
(G) instructions for utilizing at least one of: the first data to adjust the CVD process, the second data to adjust the litho and etch process, and the third data to adjust the CMP process, for the other semiconductor product subsequent to the at least one semiconductor product; and
(H) instructions for determining a variation in resistance over the plurality of semiconductor products including the at least one semiconductor product.
